(19) United States
(12) Patent Application Publication
(10) Pub. No.: US 2013/0234183 A1
(43) Pub. Date: Sep. 12, 2013

(54) LED MODULE

(71) Applicants: MING-TA TSAI, Hukou (TW); CHAO-HSIUNG CHANG, Hukou (TW)

(72) Inventors: MING-TA TSAI, Hukou (TW); CHAO-HSIUNG CHANG, Hukou (TW)

(73) Assignee: ADVANCED OPTOELECTRONIC TECHNOLOGY, INC., Hsinchu Hsien 303 (TW)

(21) Appl. No.: 13/615,657

(22) Filed: Sep. 14, 2012

(30) Foreign Application Priority Data
Mar. 6, 2012 (CN) 201210056405.8

(51) Int. Cl. H01L 33/58; H01L 33/60

(52) U.S. Cl. 257/98; 257/E33.073; 257/E33.072

(57) ABSTRACT

An LED module comprises an LED chip and a lens matching with the LED chip. The lens comprises a light-guiding portion and a rough portion protruded from the light-guiding portion. A cavity is defined in a bottom of the light-guiding portion. The LED chip is received in the cavity. The light-guiding portion comprises a top surface. Part of light emitted from the LED chip is reflected to an interior of the lens by the top surface of the light-guiding portion, and traveling to the rough portion then being reflected or refracted by the rough portion, and finally traveling out of the lens through the top surface of the light-guiding portion.

### BACKGROUND

1. Technical Field

The present disclosure generally relates to light sources, and particularly to a light emitting diode (LED) module having good light output efficiency.

2. Description of Related Art

LEDs have many advantages, such as high luminosity, low operational voltage, low power consumption, compatibility with integrated circuits, faster switching, long term reliability, and environmental friendliness which have promoted their wide use as a light source.

A conventional LED generally generates a smooth round light field with a radiation angle of 114 degrees. The light emitted from the LED is mainly concentrated at a center thereof. The light at a periphery of the LED is relatively poor and can not be used to illuminate. Therefore, light output efficiency of the conventional LED is decreased.

What is needed therefore is an LED which can overcome the above mentioned limitations.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure.

FIG. 1 is an exploded, cross-sectional view of an LED module according to an exemplary embodiment of the present disclosure.

FIG. 2 is an assembled view of the LED module of FIG. 1.

FIG. 3 is a schematic view showing light paths of the LED module of FIG. 2.

### DETAILED DESCRIPTION

Reference will now be made to the drawings to describe the present LED module 1, in detail.

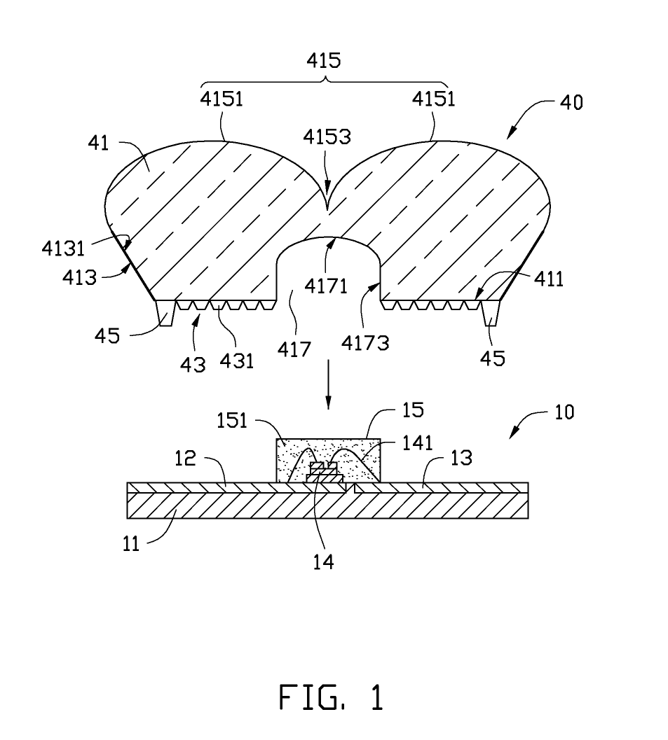

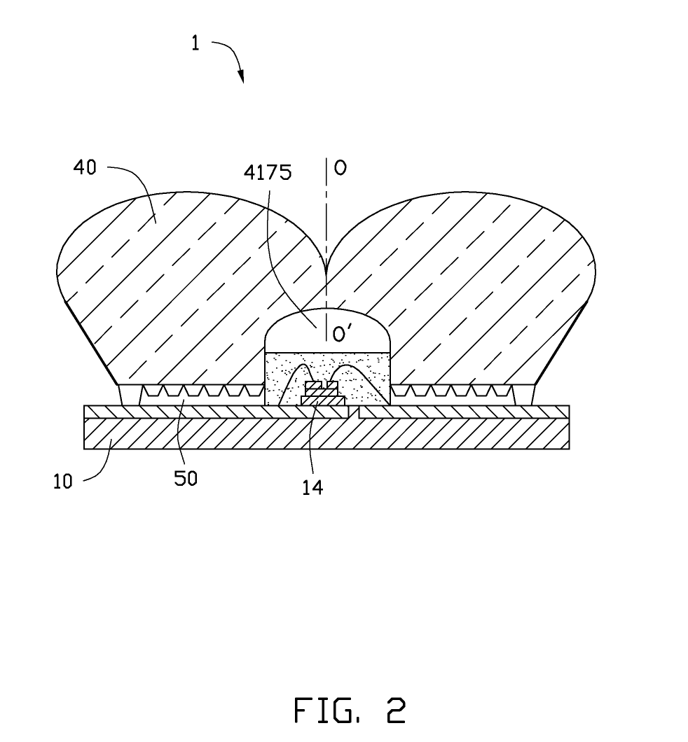

Referring to FIG. 1 and FIG. 2, the LED module 1 includes an LED 10 and a lens 40 matching with the LED 10.

The LED 10 includes a substrate 11, a first electrode 12, a second electrode 13, an LED chip 14 and an encapsulant 15. The substrate 11 is flat. The first electrode 12 and the second electrode 13 are arranged on a top surface of the substrate 11 and spaced from each other. The LED chip 14 is mounted on a top surface of the first electrode 12. The LED chip 14 is electrically connected to the first electrode 12 and the second electrode 13 via metal wires 141, respectively. The encapsulant 15 encapsulates the LED chip 14 therein. The encapsulant 15 is made by epoxy, silicon, glass or other transparent materials which have good light-permeable and water-proof capabilities. In this embodiment, a plurality of fluorescent powder 151 may be doped within the encapsulant 15 to adjust the color of the light emitted from the LED chip 14.

The lens 40 covers the encapsulant 15 and the LED chip 14 to change the path of the light emitted from the LED chip 14, thereby improving the utilization rate of the light. The lens 40 is made of a transparent material with a good optical performance, such as PMMA (polymethyl methacrylate), PC (Polycarbonate) plastic. The lens 40 is symmetrical with respect to a virtual central axis O-O′ line (as shown in FIG. 2).

The lens 40 includes a light-guiding portion 41, a rough portion 43 and a pair of retaining portions 45.

The light-guiding portion 41 includes a curved top surface 415, a flat bottom surface 411 and an annular side surface 413 interconnecting edges of the top surface 415 and the bottom surface 411. A width of the top surface 415 along a direction parallel to the top surface of the substrate 11 is larger than that of the bottom surface 411. The side surface 413 is inclined, and extends downwardly and inwardly from an edge of the top surface 415 to a corresponding edge of the bottom surface 411. The top surface 415 is employed as a light-emergent surface of the LED module 1. Most of the light emitted from the LED 10 penetrates the lens 40 from the top surface 415, and another part of the light penetrates the lens 40 from the side surface 413.

The top surface 415 includes a pair of first curved surfaces 4151 cooperatively forming a wing-shaped configuration. The first curved surfaces 4151 are symmetrical about the virtual central axis 0-0′ line. Each of the first curved surfaces 4151 is convex. Outer edges of each first curved surface 4151 respectively connect a top edge of the side surface 413. Inner edges of the two first curved surfaces 4151 intersect at a joint 4153. The joint 4153 is located on the virtual central axis O-O′ line. A distance between each first curved surface 4151 and the bottom surface 411 of the light-guiding portion 41 is decreased from a central portion of the first curved surface 4151 to a periphery of the first curved surface 4151.

A cavity 417 is recessed from a central portion of the bottom surface 411 to receive the LED chip 14 therein. The cavity 417 is surrounded by a second curved surface 4171 and an annular surface 4173 connecting the second curved surface 4171. The second curved surface 4171 is convex to form a dome. The center of the second curved surface 4171 is aligned with the joint 4153. The annular surface 4173 is perpendicular to the substrate 11. The second curved surface 4171 and the annular surface 4173 is employed as a light input surface of the lens 40. A width of the cavity 417 along the direction parallel to the top surface of the substrate 11 equals that of the encapsulant 15.

A reflecting layer 4131 is filmed to an inner surface of the side surface 413 to reflect a part of the light radiated towards the side surface 413 to make the reflected light radiate through the top surface 415 of the light guiding portion 41 to enhance a light output efficiency of the LED module 1. The reflecting layer 4131 is inclined, and extends upwardly and outwardly along the side surface 413. Preferably, an angle between the reflecting layer 4131 and the bottom surface 411 is in a range from about 30 to 45 degrees.

The rough portion 43 and the two retaining portions 45 are protruded downwardly from the bottom surface 411. The rough portion 43 includes a plurality of continuous protruding portions 431. The protruding portions 431 are evenly arrayed on the bottom surface 411 and located around the cavity 417. Each protruding portion 431 has the same shape and size. Each protruding portion 431 is inverted trapeziform, and a width of the protruding portion 431 decreases from a top end connecting the bottom surface 411 to a bottom end away from the bottom surface 411. An inner surface of each protruding portion 431 may be covered by a reflecting film (not shown) to reflect light back to the interior of the lens 40. Edges of top ends of adjacent protruding portions 431 connect with each other, and the another parts of the adjacent protruding portions 431 are spaced from each other. The outer edges of the two protruding portions 431 located at outmost sides of the bottom surface 411 connect inner edges of the two retaining portions 45 respectively.

The lens 40 are fixed on the first electrode 12 and the second electrode 13 of the LED 10 by the retaining portions 45. Each retaining portion 45 is also inverted trapeziform. A width of the retaining portion 45 is decreased from a top end connecting the bottom surface 411 to a bottom end away from the bottom surface 411. A height of the retaining portion 45 is larger than that of the protruding portions 413.

Referring to FIG. 2, when the lens 40 is fixed with the LED 10, the retaining portions 45 are mounted on the first electrode 12 and the second electrode 13 respectively. The rough portion 43 is located above and spaced from the two electrodes 12, 13. A gap 50 is defined between the rough portion 43 and the two electrodes 12, 13 to receive cool air therein to cool the LED chip 14. The encapsulant 15 is received in the cavity 417, and the side surface of the encapsulant 15 intimately contacts the annular surface 4173. The top end of the encapsulant 15 is spaced from the second curved surface 4171. An air chamber 4175 is defined between the top end of the encapsulant 15 and the second curved surface 4171. Meanwhile, the LED chip 14 is under the second curved surface 4171. A distance between the LED chip 14 and the second curved surface 4171 is larger than the focal length of the second curved surface 4171. In this state, light emitted from the LED chip 14 may evenly radiates out of the lens 40.

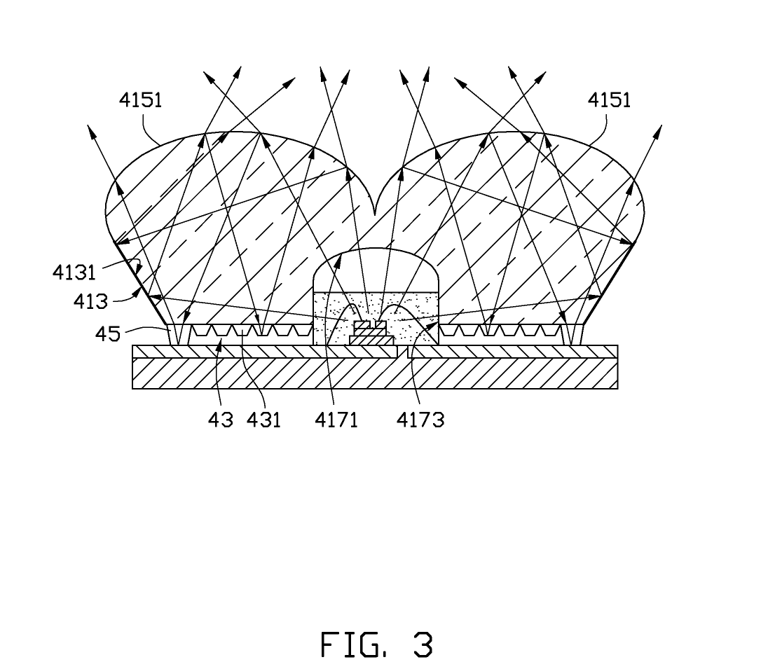

Referring to FIG. 3, during operation of the LED module 1, a part of light emitted from the LED chip 14 travels to the first curved surface 4151 from the second curved surface 4171 or the annular surface 4173 of the cavity 417, and another part of the light travels to the side surface 413. A part of the light arrived at the first curved surface 4151 directly travels out of the lens 40, and another part of the light arrived at the first curved surface 4151 is reflected back to the light-guiding portion 41, the retaining portions 45 or the rough portion 43. Most part of the light arrived at the side surface 413 is directly or indirectly reflected by the reflecting layer 4131 to travel out of the lens 40 through the first curved surface 4151, and another part is reflected to the retaining portions 45 or the rough portion 43. The light radiated to the retaining portions 45 or the rough portion 43 is reflected or refracted by the retaining portions 45 or the rough portion 43 to travel out of the lens 40 through the first curved surface 4151.

In the conventional LED module, some light may be leaked from the side surface or the bottom surface. However, in the present disclosure, such part of light can be reflected or refracted back to interior of the lens 40 by reflecting layer 4131, retaining portions 45 or rough portion 43. This increases the utilization rate of the light emitted from the LED module 1.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. An LED module comprising:
an LED chip; and
a lens matching with the LED chip and comprising a light-guiding portion and a rough portion protruded from the light-guiding portion, a cavity being defined in a bottom of the light-guiding portion, the LED chip being received in the cavity, the light-guiding portion comprising a top surface, part of light emitted from the LED chip being reflected to an interior of the lens by the top surface of the light-guiding portion, and traveling to the rough portion then being reflected or refracted by the rough portion, and finally traveling out of the lens through the top surface of the light-guiding portion.

2. The LED module as claimed in claim 1, wherein the light-guiding portion further comprises a bottom surface opposite to the top surface, the rough portion comprises a plurality of continuous protruding portions, and the protruding portions are protruded downwardly from the bottom surface.

3. The LED module as claimed in claim 2, wherein each protruding portion is inverted trapeziform, and a width of the protruding portion decreases from a top end connecting the bottom surface to a bottom end away from the bottom surface.

4. The LED module as claimed in claim 3, wherein edges of top ends of adjacent protruding portions connect with each other, and another parts of the adjacent protruding portions are spaced from each other.

5. The LED module as claimed in claim 2, further comprising a substrate, a first electrode and a second electrode located on the substrate, wherein the lens further comprises two retaining portions protruded downwardly from the bottom surface of the light-guiding portion, the LED chip electrically connects the first electrode and the second electrode, and the retaining portions are mounted on the first electrode and the second electrode respectively.

6. The LED module as claimed in claim 5, wherein a gap is defined between the rough portion and the two electrodes to receive cool air therein to cool the LED chip.

7. The LED module as claimed in claim 2, wherein the light-guiding portion comprises a side surface connecting edges of the top surface and the bottom surface, and a reflecting layer is filmed to the side surface.

8. The LED module as claimed in claim 7, wherein the reflecting layer extends along the side surface, and an angle between the reflecting layer and the bottom surface is in a range from about 30 to 45 degrees.

9. The LED module as claimed in claim 1, wherein the cavity is surrounded by a second curved surface and an annular surface connecting the second curved surface, and a distance between the LED chip and the second curved surface is larger than the focal length of the second curved surface.

10. An LED module comprising:
an LED chip;
a lens matching with the LED chip and comprising a light-guiding portion, the light-guiding portion comprising a top surface acting as an light output surface of the lens, a bottom surface opposite to the top surface and a side surface interconnecting the top surface and the bottom surface; and
a reflecting layer being filmed on the side surface;
wherein part of light emitted from the LED chip radiating towards the side surface and being reflected by the reflecting layer, and then radiating towards the top surface and travelling out of the lens through the top surface of the light-guiding portion.

11. The LED module as claimed in claim 10, the reflecting layer extends along the side surface, and an angle between the reflecting layer and the bottom surface is in a range from about 30 to 45 degrees.

12. The LED module as claimed in claim 10, wherein a rough portion is protruded from the bottom surface of the light-guiding portion.

13. The LED module as claimed in claim 12, wherein the rough portion comprises a plurality of continuous protruding portions, and the protruding portions are protruded downwardly from the bottom surface.

14. The LED module as claimed in claim 13, wherein each protruding portion is inverted trapeziform, and a width of the protruding portion decreases from a top end connecting the bottom surface to a bottom end away from the bottom surface.

15. The LED module as claimed in claim 13, wherein edges of top ends of adjacent protruding portions connect with each other, and another parts of the adjacent protruding portions are spaced from each other.

16. The LED module as claimed in claim 10, wherein the top surface comprises a pair of first curved surfaces cooperatively forming a wing-shaped configuration, each of the first curved surfaces is convex, outer edges of each first curved surface respectively connect a top edge of the side surface, and inner edges of the two first curved surfaces intersect at a joint.

17. The LED module as claimed in claim 16, wherein a distance between each first curved surface and the bottom surface of the light-guiding portion is decreased from a central portion of the first curved surface to a periphery of the first curved surface.

18. The LED module as claimed in claim 10, wherein a cavity is recessed from a central portion of the bottom surface to receive the LED chip therein, and the cavity is surrounded by a second curved surface and an annular surface connecting the second curved surface.

19. The LED module as claimed in claim 18 further comprising a first electrode, a second electrode, and an encapsulant encapsulating the LED chip therein, wherein the top end of the encapsulant is spaced from the second curved surface.

20. The LED module as claimed in claim 19, wherein a distance between the LED chip and the second curved surface is larger than the focal length of the second curved surface.
